(19) United States
(12) Patent Application Publication
(10) Pub. No.: US 2019/0067034 A1
(43) Pub. Date: Feb. 28, 2019

(54) HYBRID ADDITIVE STRUCTURE STACKABLE MEMORY DIE USING WIRE BOND

(71) Applicant: Micron Technology, Inc., Boise, ID (US)

(72) Inventors: Ashok Pachamuthu, Boise, ID (US); Chan H. Yoo, Boise, ID (US); John F. Kaeding, Boise, ID (US)

(21) Appl. No.: 15/685,940

(22) Filed: Aug. 24, 2017

(51) Int. Cl. H01L 21/48; H01L 23/48; H01L 23/50; H01L 21/56; H01L 21/683; H01L 23/31

(52) U.S. Cl. CPC H01L 21/4846; H01L 23/481; H01L 23/3107; H01L 21/563; H01L 21/6835; H01L 23/50

(57) ABSTRACT

Semiconductor devices with redistribution structures that do not include pre-formed substrates and associated systems and methods are disclosed herein. In one embodiment, a semiconductor device includes a first semiconductor die attached to a redistribution structure and electrically coupled to the redistribution structure via a plurality of wire bonds. The semiconductor device can also include one or more second semiconductor dies stacked on the first semiconductor die, wherein one or more of the first and second semiconductor dies are electrically coupled to the redistribution structure via a plurality of wire bonds. The semiconductor device can also include a molded material over the first and/or second semiconductor dies and a surface of the redistribution structure.

### CROSS-REFERENCE TO RELATED APPLICATION

This application contains subject matter related to a concurrently-filed U.S. Patent Application by John F. Kaeding, Ashok Pachamuthu, Mark E. Tuttle, and Chan H. Yoo, entitled “THRUMOLD POST PACKAGE WITH REVERSE BUILD UP HYBRID ADDITIVE STRUCTURE.” The related application, of which the disclosure is incorporated by reference herein, is assigned to Micron Technology, Inc., and is identified by attorney docket number 010829-9216.US00.

### TECHNICAL FIELD

The present disclosure generally relates to semiconductor devices. In particular, the present technology relates to semiconductor devices including semiconductor dies electrically coupled to a redistribution structure that does not include a pre-formed substrate, and associated systems and methods.

### BACKGROUND

Microelectronic devices generally have a die (i.e., a chip) that includes integrated circuitry with a high density of very small components. Typically, dies include an array of very small bond pads electrically coupled to the integrated circuitry. The bond pads are external electrical contacts through which the supply voltage, signals, etc., are transmitted to and from the integrated circuitry. After dies are formed, they are “packaged” to couple the bond pads to a larger array of electrical terminals that can be more easily coupled to the various power supply lines, signal lines, and ground lines. Conventional processes for packaging dies include electrically coupling the bond pads on the dies to an array of leads, ball pads, or other types of electrical terminals, and encapsulating the dies to protect them from environmental factors (e.g., moisture, particulates, static electricity, and physical impact).

Different types of dies may have widely different bond pad arrangements, and yet should be compatible with similar external devices. Accordingly, existing packaging techniques can include electrically coupling a die to an interposer or other pre-formed substrate that is configured to mate with the bond pads of external devices. The pre-formed substrate is formed separately from the wafer, such as by a vendor, and then the pre-formed substrate is attached to the wafer during the packaging process. Such pre-formed substrates can be relatively thick, thereby increasing the size of the resulting semiconductor packages. Other existing packaging techniques can instead include forming a redistribution layer (RDL) directly on a die. The RDL includes lines and/or vias that connect the die bond pads with RDL bond pads, which are in turn arranged to mate with the bond pads of external devices. In one typical packaging process, many dies are mounted on a carrier (i.e., at the wafer or panel level) and encapsulated before the carrier is removed. Then an RDL is formed directly on a front side of the dies using deposition and lithography techniques. Finally, an array of leads, ball-pads, or other types of electrical terminals are mounted on bond pads of the RDL and the dies are singulated to form individual microelectronic devices.

One drawback with the foregoing packaging technique is that it makes it difficult and costly to vertically stack multiple semiconductor dies in a single package. Namely, because the dies are encapsulated prior to the formation of the RDL, stacked dies generally require through silicon vias (TSVs) to electrically couple bond pads of the stacked dies to the RDL. The formation of TSVs requires special tooling and/or techniques that increase the cost of forming a microelectronic device.

### BRIEF DESCRIPTION OF THE DRAWINGS

FIGS. 1A and 1B are a cross-sectional view and top plan view, respectively, illustrating a semiconductor device in accordance with an embodiment of the present technology.

FIGS. 2A-2J are cross-sectional views illustrating a semiconductor device at various stages of manufacturing in accordance with an embodiment of the present technology.

FIG. 2K is a top plan view of the semiconductor device shown in FIG. 2J.

FIGS. 3A and 3B are a cross-sectional view and top plan view, respectively, illustrating a semiconductor device in accordance with an embodiment of the present technology.

FIGS. 4A and 4B are a cross-sectional view and top plan view, respectively, illustrating a semiconductor device in accordance with an embodiment of the present technology.

FIG. 5 is a schematic view of a system that includes a semiconductor device configured in accordance with an embodiment of the present technology.

### DETAILED DESCRIPTION

Specific details of several embodiments of semiconductor devices including semiconductor dies electrically coupled to a redistribution structure that does not include a pre-formed substrate, and associated systems and methods, are described below. In some embodiments, a semiconductor device includes one or more semiconductor dies wire bonded to a redistribution structure without a pre-formed substrate and encapsulated by a molded material. In the following description, numerous specific details are discussed to provide a thorough and enabling description for embodiments of the present technology. One skilled in the relevant art, however, will recognize that the disclosure can be practiced without one or more of the specific details. In other instances, well-known structures or operations often associated with semiconductor devices are not shown, or are not described in detail, to avoid obscuring other aspects of the technology. In general, it should be understood that various other devices, systems, and methods in addition to those specific embodiments disclosed herein may be within the scope of the present technology.

As used herein, the terms “vertical,” “lateral,” “upper,” and “lower” can refer to relative directions or positions of features in the semiconductor devices in view of the orientation shown in the Figures. For example, “upper” or “uppermost” can refer to a feature positioned closer to the top of a page than another feature. These terms, however, should be construed broadly to include semiconductor devices having other orientations, such as inverted or inclined orientations where top/bottom, over/under, above/below, up/down and left/right can be interchanged depending on the orientation.

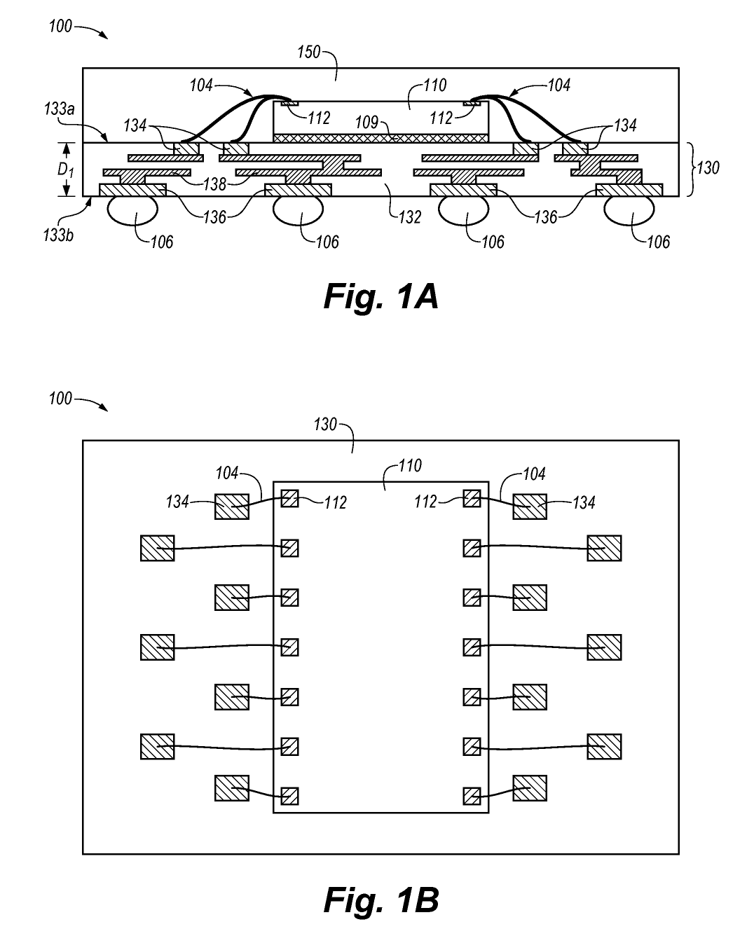

FIG. 1A is a cross-sectional view, and FIG. 1B is a top plan view, illustrating a semiconductor device 100 (“device 100”) in accordance with an embodiment of the present technology. With reference to FIG. 1A, the device 100 can include a redistribution structure 130, a semiconductor die 110 coupled to the redistribution structure 130 and having a plurality of bond pads 112, and a molded material 150 over at least a portion of the redistribution structure 130 and the semiconductor die 110. The molded material 150 can completely cover the semiconductor die 110 and the redistribution structure 130. As shown in FIG. 1A, only one semiconductor die 110 is coupled to the redistribution structure 130, however, in other embodiments, the device 100 may include any number of semiconductor dies (e.g., one or more additional semiconductor dies stacked on the semiconductor die 110). The semiconductor die 110 can include various types of semiconductor components and functional features, such as dynamic random-access memory (DRAM), static random-access memory (SRAM), flash memory, other forms of integrated circuit memory, processing circuits, imaging components, and/or other semiconductor features. In some embodiments, the device 100 can include a die-attach material 109 disposed between the semiconductor die 110 and a first surface 133a of the redistribution structure 130. The die-attach material 109 can be, for example, an adhesive film (e.g. a die-attach film), epoxy, tape, paste, or other suitable material.

The redistribution structure 130 includes a dielectric material 132, a plurality of first contacts 134 in and/or on the dielectric material 132, and a plurality of second contacts 136 in and/or on the dielectric material 132. The redistribution structure 130 further includes a plurality of conductive lines 138 (e.g., comprising conductive vias and/or traces) extending within, through, and/or on the dielectric material 132 to electrically couple individual ones of the first contacts 134 to corresponding ones of the second contacts 136. In certain embodiments, the first contacts 134, second contacts 136, and conductive lines 138 can be formed from one or more conductive materials such as copper, nickel, solder (e.g., SnAg-based solder), conductor-filled epoxy, and/or other electrically conductive materials. The dielectric material 132 can comprise one or more layers of a suitable dielectric, insulating, or passivation material. The dielectric material 132 electrically isolates individual first contacts 134, second contacts 136, and associated conductive lines 138 from one another. The redistribution structure 130 also includes the first surface 133a which faces the semiconductor die 110 and a second surface 133b opposite the first surface 133a. The first contacts 134 are exposed at the first surface 133a of the redistribution structure 130 while the second contacts 136 are exposed at the second surface 133b of the redistribution structure 130.

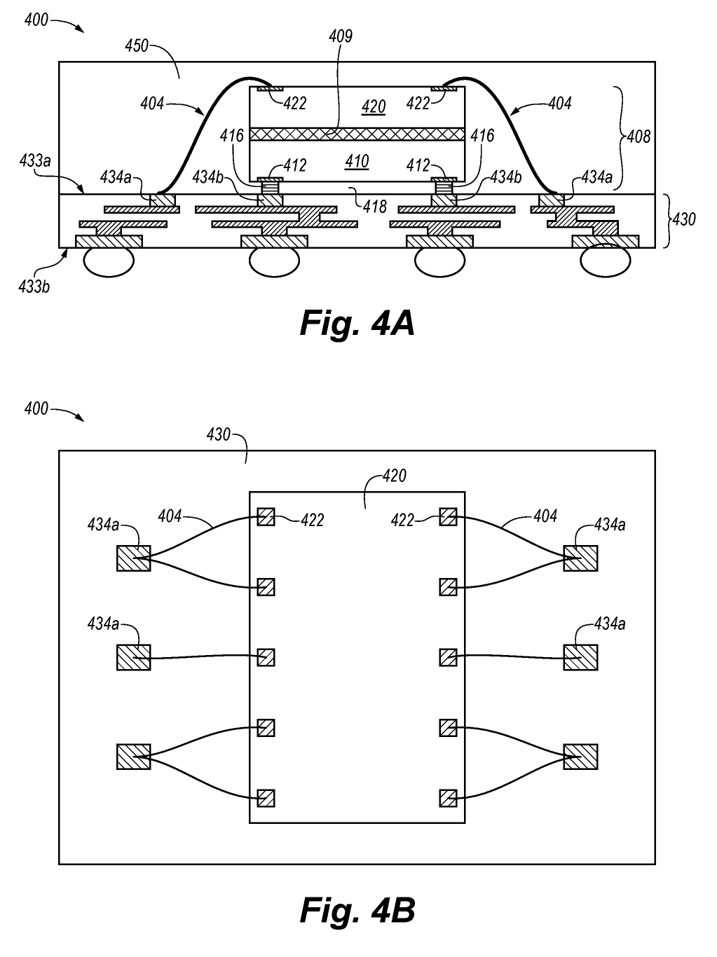

In some embodiments, one or more of the second contacts 136 of the redistribution structure 130 are spaced laterally farther from the semiconductor die 110 than the corresponding first contacts 134. That is, some of the second contacts 136 can be fanned out or positioned laterally outboard of the corresponding first contacts 134 to which they are electrically coupled. Positioning the second contacts 136 laterally outboard of the first contacts 134 facilitates connection of the device 100 to other devices and/or interfaces having connections with a greater pitch than that of the semiconductor die 110. Moreover, the redistribution structure 130 can include a die-attach area under the semiconductor die 110. In the embodiment shown in FIG. 1A, none of the first contacts 134 are disposed within the die-attach area of the redistribution structure 130. In other embodiments (e.g., as shown in FIG. 4A), one or more of the first contacts 134 can be disposed within the die-attach area under the semiconductor die 110. When first contacts 134 are within the die-attach area, the first contacts 134 can be electrically active or dummy contacts that are not electrically active.

The dielectric material 132 of the redistribution structure 130 forms a built-up substrate such that the redistribution structure 130 does not include a pre-formed substrate (e.g., a substrate formed apart from a carrier wafer and then subsequently attached to the carrier wafer). The redistribution structure 130 can therefore be made very thin. For example, in some embodiments, a distance D₁ between the first and second surfaces 133a and 133b of the redistribution structure 130 is less than about 50 μm. In certain embodiments, the distance D₁ is approximately 30 μm, or less than about 30 μm. Therefore, the overall size of the semiconductor device 100 can be reduced as compared to, for example, devices including a conventional redistribution layer formed over a pre-formed substrate. However, the thickness of the redistribution structure 130 is not limited.

The device 100 further includes (i) first electrical connectors 104 electrically coupling the bond pads 112 of the semiconductor die 110 to corresponding first contacts 134 of the redistribution structure 130, and (ii) second electrical connectors 106 disposed on the second surface 133b of the redistribution structure 130 and configured to electrically couple the second contacts 136 of the redistribution structure 130 to external circuitry (not shown). The second electrical connectors 106 can be solder balls, conductive bumps, conductive pillars, conductive epoxies, and/or other suitable electrically conductive elements. In some embodiments, the second electrical connectors 106 form a ball grid array on the second surface 133b of the redistribution structure 130. In certain embodiments, the second electrical connectors 106 can be omitted and the second contacts 136 can be directly connected to external devices or circuitry. As shown in FIG. 1A, the first electrical connectors 104 can comprise a plurality of wire bonds. In other embodiments, the first electrical connectors 104 can comprise other types of electrically conductive connectors (e.g., conductive pillars, bumps, lead frame, etc.).

FIG. 1B is a top plan view of the device 100 showing the semiconductor die 110 and the bond pads 112 (the molded material 150 is not shown for ease of illustration). As shown, the first electrical connectors 104 electrically couple bond pads 112 of the semiconductor die 110 to corresponding ones of the first contacts 134 of the redistribution structure 130. In some embodiments, an individual first contact 134 can be electrically coupled to more than one bond pad 112, or to only a single bond pad 112. In this manner, the device 100 may be configured such that individual pins of the semiconductor die 110 are individually isolated and accessible (e.g., signal pins), and/or configured such that multiple pins are collectively accessible via the same set of first and second contacts 134 and 136 (e.g., power supply or ground pins). In other embodiments, the electrical connectors 104 can be arranged in any other manner to provide a different configuration of electrical couplings between the semiconductor die 110 and the first contacts 134 of the redistribution structure 130.

As further shown in FIG. 1B, the semiconductor die 110 can have a rectangular shape in which the bond pads 112 are arranged along opposing longitudinal sides of the semiconductor die 110. However, in other embodiments, the semiconductor die 110 can have any other shape and/or bond pad configuration. For example, the semiconductor die 110 can be rectangular, circular, square, polygonal, and/or other suitable shapes. The semiconductor die 110 can further include any number of bond pads (e.g., more or less than the 10 example bond pads 112 shown in FIG. 1B) that can be arranged in any pattern on the semiconductor die 110.

Referring again to FIG. 1A, the molded material 150 can be formed over the first surface 133a of the redistribution structure 130, the semiconductor die 110, and the first electrical connectors 104. The molded material 150 can encapsulate the semiconductor die 110 to protect the semiconductor die 110 from contaminants and physical damage. Moreover, since the device 100 does not include a pre-formed substrate, the molded material 150 also provides the desired structural strength for the device 100. For example, the molded material 150 can be selected to prevent the device 100 from warping, bending, etc., as external forces are applied to the device 100. As a result, in some embodiments, the redistribution structure 130 can be made very thin (e.g., less than 50 μm) since the redistribution structure 130 need not provide the device 100 with a great deal of structural strength. Therefore, the overall height (e.g., thickness) of the device 100 can be reduced.

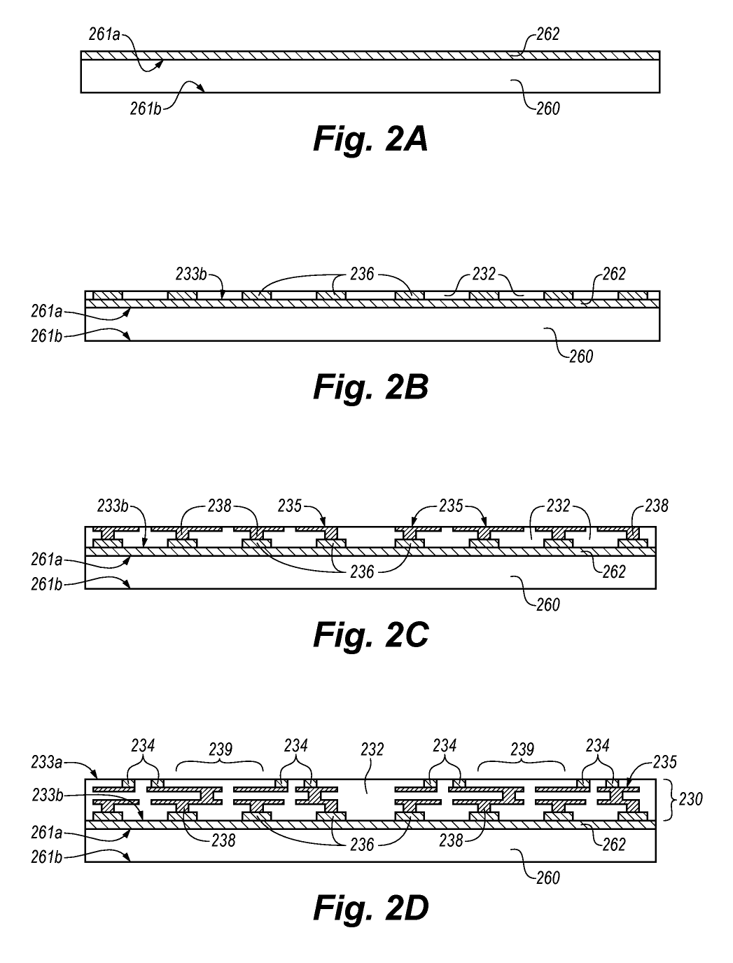

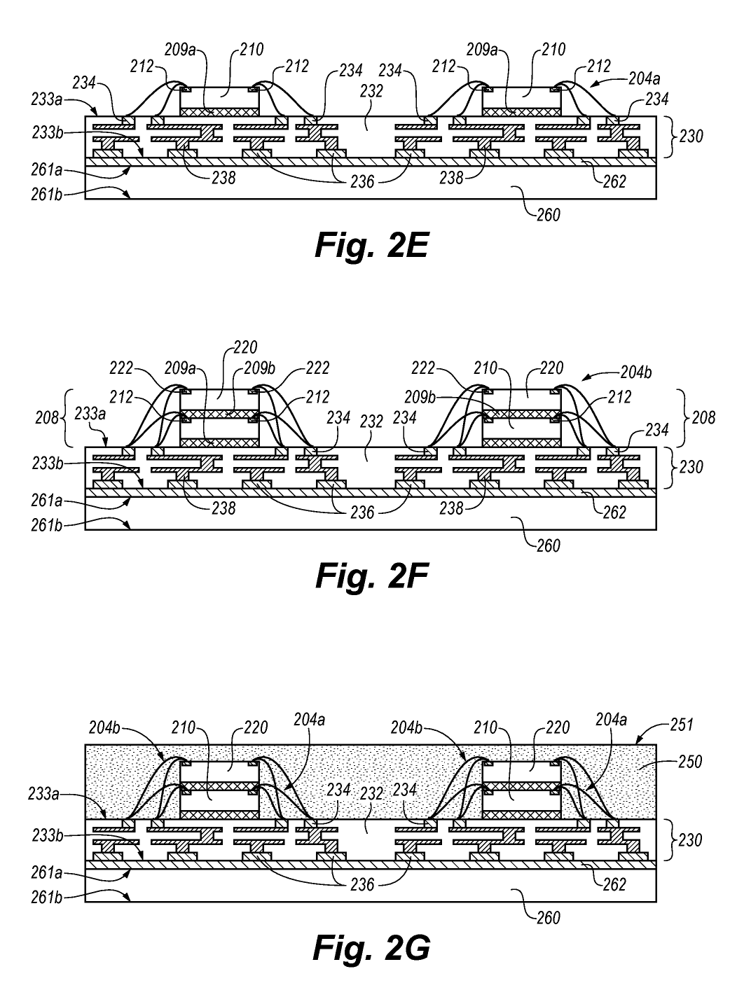

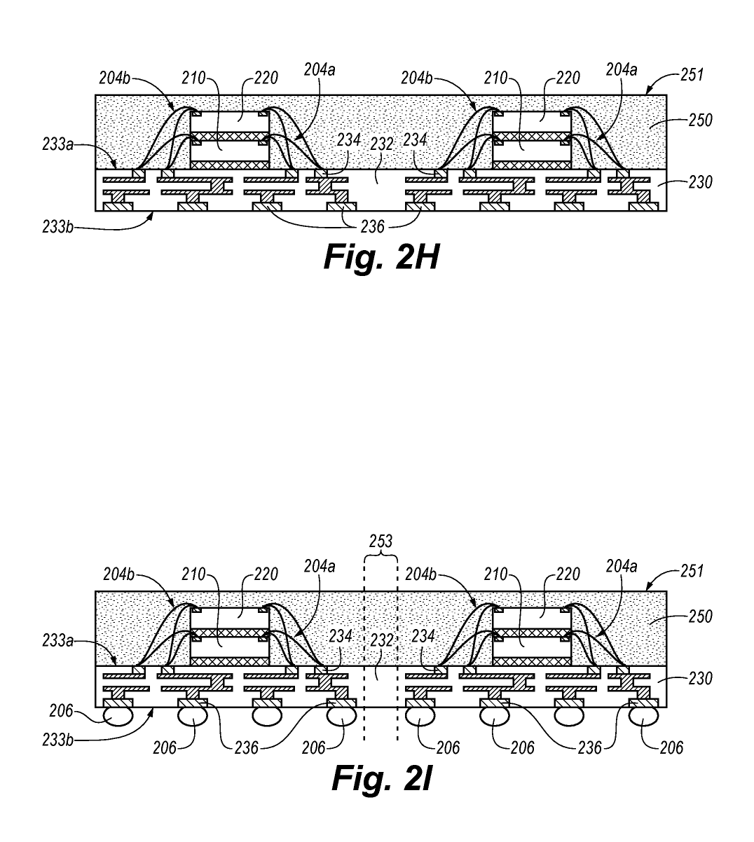

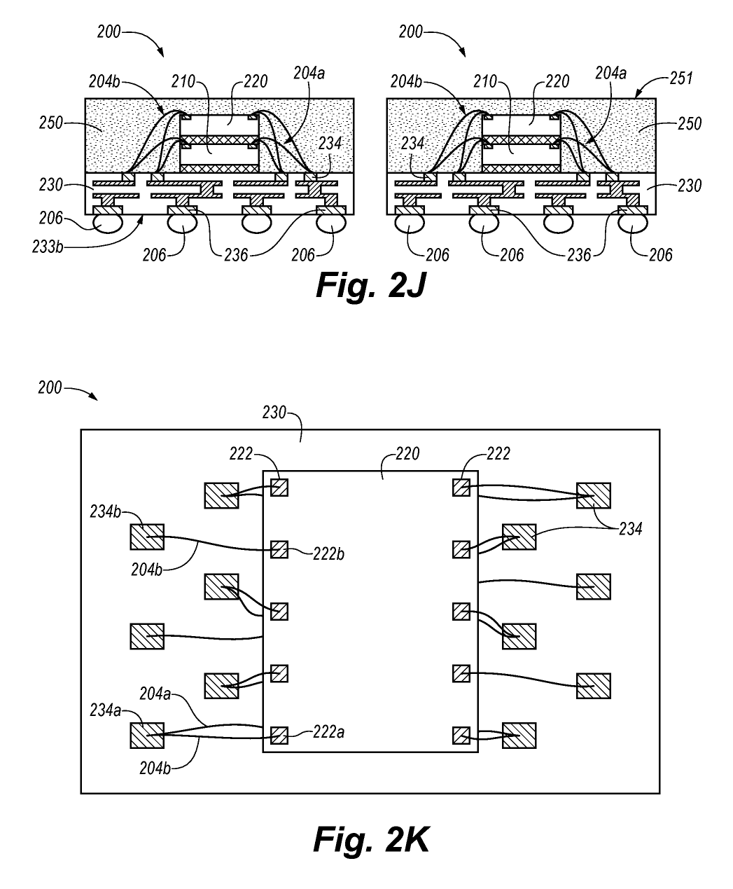

FIGS. 2A-2J are cross-sectional views illustrating various stages in a method of manufacturing semiconductor devices 200 in accordance with embodiments of the present technology. Generally, the semiconductor device 200 can be manufactured, for example, as a discrete device or as part of a larger wafer or panel. In wafer-level or panel-level manufacturing, a larger semiconductor device is formed before being singulated to form a plurality of individual devices. For ease of explanation and understanding, FIGS. 2A-2J illustrate the fabrication of two semiconductor devices 200. However, one skilled in the art will readily understand that the fabrication of semiconductor devices 200 can be scaled to the wafer and/or panel level—that is, to include many more components so as to be capable of being singulated into more than two semiconductor devices—while including similar features and using similar processes as described herein.

Referring first to FIGS. 2A-2D, fabrication of the semiconductor devices 200 begins with the formation of a redistribution structure 230 (FIG. 2D). Referring to FIG. 2A, a carrier 260 having a front side 261a and a back side 261b is provided, and a release layer 262 is formed on the front side 261a of the carrier 260. The release layer 262 prevents direct contact of the redistribution structure 230 with the carrier 260 and therefore protects the redistribution structure 230 from possible contaminants on the carrier 260. In certain embodiments, the carrier 260 can be a temporary carrier formed from, e.g., silicon, silicon-on-insulator, compound semiconductor (e.g., Gallium Nitride), glass, or other suitable materials. In part, the carrier 260 provides mechanical support for subsequent processing stages, and also protects a surface of the release layer 262 during the subsequent processing stages to ensure the release layer 262 can be later properly removed from the redistribution structure 230. In some embodiments, the carrier 260 can be reused after it is subsequently removed. The release layer 262 can be a disposable film (e.g., a laminate film of epoxy-based material) or other suitable material. In some embodiments, the release layer 262 can be laser-sensitive or photo-sensitive to facilitate its removal via a laser or other light source at a subsequent stage.

The redistribution structure 230 (FIG. 2D) is a hybrid structure of conductive and dielectric materials that can be formed from an additive build-up process. That is, the redistribution structure 230 is additively built directly on the carrier 260 and the release layer 262 rather than on another laminate or organic substrate. Specifically, the redistribution structure 230 is fabricated by semiconductor wafer fabrication processes such as sputtering, physical vapor deposition (PVD), electroplating, lithography, etc. For example, referring to FIG. 2B, a plurality of second contacts 236 can be formed directly on the release layer 262, and a layer of dielectric material 232 can be formed on the release layer 262 to electrically isolate the individual second contacts 236. The dielectric material 232 may be formed from, for example, parylene, polyimide, low temperature chemical vapor deposition (CVD) materials—such as tetraethylorthosilicate (TEOS), silicon nitride (Si₃Ni₄), silicon oxide (SiO₂)—and/or other suitable dielectric, non-conductive materials. Referring to FIG. 2C, additional layers of conductive material and dielectric material 232 can be formed to build up the dielectric material 232 and the conductive lines 238 that form conductive portions 235 within the dielectric material 232.

FIG. 2D shows the redistribution structure 230 after being fully formed on the release layer 262 and carrier 260. As shown in FIG. 2D, a plurality of first contacts 234 are formed to be electrically coupled to the conductive lines 238. The conductive portions 235 of the redistribution structure 230 can accordingly include the second contacts 236 and one or more of the first contacts 234 and conductive lines 238. The conductive portions 235 can be made from copper, nickel, solder (e.g., SnAg-based solder), conductor-filled epoxy, and/or other electrically conductive materials. In some embodiments, the conductive portions 235 are all made from the same conductive material. In other embodiments, each conductive portion 235 may include more than one conductive material (e.g., the first contacts 234, second contacts 236, and conductive lines 238 can comprise one or more conductive materials), and/or different conductive portions 235 can comprise different conductive materials. The first contacts 234 can be arranged to define die-attach areas 239 on the redistribution structure 230.

Referring to FIG. 2E, fabrication of the semiconductor devices 200 continues with coupling a plurality of first semiconductor dies 210 to die-attach areas of the redistribution structure 230, and forming a plurality of electrical connectors 204a electrically coupling the first semiconductor dies 210 to the redistribution structure 230. More specifically, a back side of the first semiconductor dies 210 (e.g., a side opposite a front side having bond pads 212) is attached to a die-attach area at an exposed upper surface 233a of the redistribution structure 230 via a first die-attach material 209a. The first die-attach material 209a can be a die-attach adhesive paste or an adhesive element, for example, a die-attach film or a dicing-die-attach film (known to those skilled in the art as “DAF” or “DDF,” respectively). In one embodiment, the first die-attach material 209a can include a pressure-set adhesive element (e.g., tape or film) that adheres the first semiconductor dies 210 to the redistribution structure 230 when it is compressed beyond a threshold level of pressure. In another embodiment, the first die-attach material 209a can be a UV-set tape or film that is set by exposure to UV radiation. As further shown in FIG. 2E, the bond pads 212 of the first semiconductor dies 210 are electrically coupled to corresponding first contacts 234 of the redistribution structure 230 via the electrical connectors 204a. In the illustrated embodiment, the electrical connectors 204a comprise a plurality of wire bonds. In other embodiments, the electrical connectors 204a may comprise another type of conductive feature such as, for example, conductive bumps, pillars, lead frame, etc. In other embodiments, the first semiconductor dies 210 may be positioned so as to have a different orientation. For example, as described in further detail below with reference to FIG. 4A, the first semiconductor dies 210 can be positioned face down such that the front side of each first semiconductor die 210 faces the redistribution structure 230.

Referring to FIG. 2F, fabrication of the semiconductor devices 200 continues with stacking a plurality of second semiconductor dies 220 on the first semiconductor dies 210, and forming a plurality of electrical connectors 204b electrically coupling the second semiconductor dies 220 to the redistribution structure 230. Accordingly a plurality of die stacks 208 are separated from each other along the redistribution structure 230. As illustrated in FIG. 2E, only two die stacks 208 are positioned on the redistribution structure 230. However, any number of die stacks 208 can be spaced apart from each other along the redistribution structure 230 and carrier 260. For example, at the wafer or panel level, many die stacks 208 can be spaced apart along the wafer or panel. In other embodiments, each die stack 208 can include a different number of semiconductor dies. For example, each die stack 208 may include only the first semiconductor die 210 (e.g., as in the embodiment illustrated in FIGS. 1A and 1B), or may include additional semiconductor dies stacked on the second semiconductor die 220 (e.g., stacks of three, four, eight, ten, or even more dies).

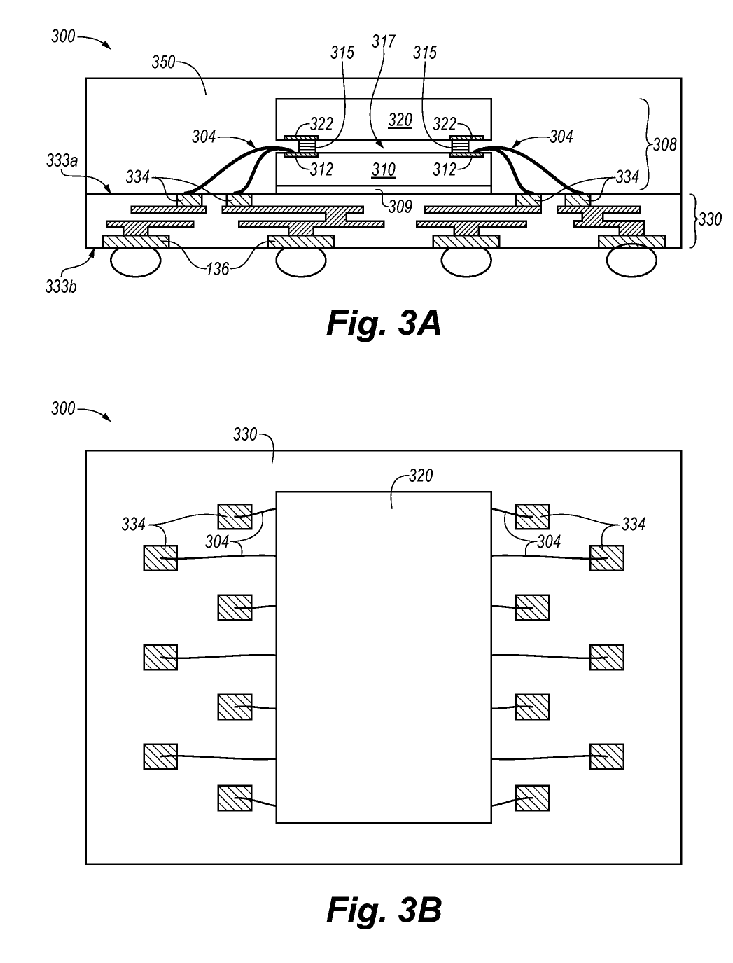

As shown in FIG. 2F, a back side of the second semiconductor dies 220 (e.g., a side opposite a front side having bond pads 222) is attached to the front side of the first semiconductor dies 210 via a second die-attach material 209b. That is, the first semiconductor dies 210 and the second semiconductor dies 220 (collectively “dies 210, 220”) are stacked front-to-back. In other embodiments, the second semiconductor die 220 can be positioned so as to have a different orientation. For example, as described in further detail below with reference to FIG. 3A, the second semiconductor dies 220 can be positioned face down such that the front side of the semiconductor dies 220 faces the front side of the first semiconductor dies 210. The second die-attach material 209b can be the same as or different than the first die-attach material 209a. In some embodiments, the second die-attach material 209b has the form of a “film-over-wire” material suitable for use with wire bonds. In such embodiments, the second die-attach material 209b can be DAF or DDF. Moreover, the thickness of the second die-attach material 209b can be sufficiently large to prevent contact between the back side of the second semiconductor dies 220 and the electrical connectors 204a (e.g., wire bonds) to avoid damaging the electrical connectors 204a. In other embodiments, the semiconductor dies 220 can be directly coupled to the semiconductor dies 210 using solder or other suitable direct die attachment techniques.

As further shown in FIG. 2F, the bond pads 222 of the second semiconductor dies 220 are electrically coupled to corresponding ones of the first contacts 234 of the redistribution structure 230 via the electrical connectors 204b. In the illustrated embodiment, the electrical connectors 204b comprise a plurality of wire bonds. In other embodiments, the electrical connectors 204b may comprise another type of conductive feature such as, for example, conductive bumps, pillars, lead frame, etc. For example, in certain embodiments where the dies 210, 220 are arranged face-to-face (i.e., front-to-front), one or more of the bond pads 222 of the second semiconductor dies 220 can be directly electrically coupled to the bond pads 212 of a first semiconductor die 210 via copper pillars or a solder connection. As described in further detail below with reference to FIG. 2K, some first contacts 234 of the redistribution structure 230 may be electrically coupled to two or more bond pads 212 and/or 222 of the dies 210, 220. In the cross-sectional view shown in FIG. 2F, only first contacts 234 electrically coupled to both the dies 210, 220 are pictured.

By forming the redistribution structure 230 on the carrier 260 before mounting the stacked dies 210, 220 on the carrier 260, conventional methods for electrically coupling the dies 210, 220 to the redistribution structure 230 can be employed (e.g., wire bonding, direct chip attach, etc.). Specifically, the use of through silicon vias (TSVs) to electrically couple stacked semiconductor dies can be avoided. TSVs are required in processes that involve first mounting a plurality of semiconductor dies to a carrier and then forming a redistribution layer directly on the dies. In such a “redistribution layer last” approach, the semiconductor dies must be stacked prior to the formation of the redistribution layer and before over-molding. That is, the semiconductor dies need to employ TSVs—as opposed to, e.g., wire bonds—because the dies are stacked and molded over prior to the formation of the redistribution layer. The present technology permits the use of other types of electrical couplings while also avoiding costs and manufacturing difficulties associated with TSVs.

Turning to FIG. 2G, fabrication of the semiconductor devices 200 continues with forming a molded material 250 on the upper surface 233a of the redistribution structure 230 and around the dies 210, 220. In the illustrated embodiment, the molded material 250 encapsulates the dies 210, 220 such that the dies 210, 220 are sealed within the molded material 250. In some embodiments, the molded material 250 can also encapsulate some or all of the electrical connectors 204a and/or 204b. The molded material 250 may be formed from a resin, epoxy resin, silicone-based material, polyimide and/or other suitable resin used or known in the art. Once deposited, the molded material 250 can be cured by UV light, chemical hardeners, heat, or other suitable curing methods known in the art. The cured molded material 250 can include an upper surface 251. In certain embodiments, the upper surface 251 may be formed and/or ground back such that upper surface 251 has a height above the upper surface 233a of the redistribution structure 230 that is only slightly greater than a maximum height of the electrical connectors 204b and/or the second semiconductor dies 220 above the upper surface 233a of the redistribution structure 230. That is, the upper surface 251 of the molded material 250 can have a height just great enough to encapsulate the electrical connectors 204b and the dies 210, 220.

Referring to FIG. 2H, fabrication of the semiconductor devices 200 continues with removing the redistribution structure 230 from the carrier 260 (shown in FIG. 2G). For example, a vacuum, poker pin, laser or other light source, or other suitable method known in the art can detach the redistribution structure 230 from the release layer 262 (FIG. 2G). In some embodiments, the release layer 262 allows the carrier 260 to be easily removed such that the carrier 260 can be reused again. In other embodiments, the carrier 260 and release layer 262 can be at least partly removed by thinning the carrier 260 and/or release layer 262 (e.g., back grinding, dry etching processes, chemical etching processes, chemical mechanical polishing (CMP), etc.). Removing the carrier 260 and release layer 262 exposes the lower surface 233b of the redistribution structure 230, including the plurality of second contacts 236.

Turning to FIG. 2I, fabrication of the semiconductor devices 200 continues with forming electrical connectors 206 on the second contacts 236 of the redistribution structure 230. The electrical connectors 206 can be configured to electrically couple the second contacts 236 of the redistribution structure 230 to external circuitry (not shown). In some embodiments, the electrical connectors 206 comprise a plurality of solder balls or solder bumps. For example, a stenciling machine can deposit discrete blocks of solder paste onto the second contacts 236 of the redistribution structure 230. The solder paste can then reflowed to form solder balls or solder bumps on the second contacts 236.

FIG. 2J shows the semiconductor devices 200 after being singulated from one another. As shown, the redistribution structure 230 can be cut together with the molded material 250 at a plurality of dicing lanes 253 (illustrated in FIG. 2I) to singulate the die stacks 208 and to separate the semiconductor devices 200 from one another. Once singulated, the individual semiconductor devices 200 can be attached to external circuitry via the electrical connectors 206 and thus incorporated into a myriad of systems and/or devices.

FIG. 2K illustrates a top plan view of one of the semiconductor devices 200. The molded material 250 has been omitted to show the second semiconductor die 220 with bond pads 222. In the illustrated embodiment, the first semiconductor die 210 is positioned entirely below the second semiconductor die 220. As shown, the electrical connectors 204a electrically couple bond pads 212 (not pictured) of the first semiconductor die 210 to corresponding ones of the first contacts 234 of the redistribution structure 230. Likewise, the electrical connectors 204b electrically couple bond pads 222 of the second semiconductor die 220 to corresponding ones of the first contacts 234 of the redistribution structure 230. In some embodiments, an individual first contact 234 can be electrically coupled to more than one bond pad 212 and/or 222. For example, as illustrated, an individual first contact 234a can be electrically coupled to an individual bond pad 222a of the second semiconductor die 220 via a wire bond 204b, and also electrically coupled to an individual bond pad 212 (not pictured) of the first semiconductor die 210 via a wire bond 204a. In certain embodiments, an individual first contact 234 can be coupled to only one bond pad 212 or 222. For example, as illustrated, an individual first contact 234b is electrically coupled only to a bond pad 222b of the second semiconductor die 220 and is therefore not electrically coupled to the first semiconductor die 210. In this manner, the device 200 may be configured such that individual pins of a semiconductor die in the die stack 208 are individually isolated and accessible (e.g., signal pins), and/or configured such that pins common to each semiconductor die in the die stack 208 are collectively accessible via the same set of first and second contacts 234 and 236 (e.g., power supply or ground pins). In other embodiments, the electrical connectors 204a and 204b can be arranged in any other manner to provide a different configuration of electrical couplings between the dies 210, 220 and the first contacts 234 of the redistribution structure 230.

In other embodiments, the dies 210, 220 can be stacked such the first semiconductor die 210 is not directly below the second semiconductor die 220, and/or the dies 210, 220 can have different dimensions or orientations from one another. For example, the second semiconductor die 220 can be mounted such that it has a portion that overhangs the first semiconductor die 210, or the first semiconductor die 210 may be larger than the second semiconductor die 220 such that the second semiconductor die 220 is positioned entirely within a footprint of the first semiconductor die 210. The dies 210, 220 can further include any number of bond pads (e.g., more or less than the 10 example bond pads shown in FIG. 2K) that can be arranged in any pattern on the dies 210, 220.

FIG. 3A is a cross-sectional view, and FIG. 3B is a top plan view, illustrating a semiconductor device 300 (“device 300”) in accordance with another embodiment of the present technology. This example more specifically shows one or more semiconductor dies arranged in a “face-to-face” configuration. The device 300 can include features generally similar to those of the semiconductor devices 100 and 200 described in detail above. For example, in the embodiment illustrated in FIG. 3A, the device 300 includes a redistribution structure 330 and a die stack 308 coupled to an upper surface 333a of the redistribution structure 330. More specifically, a backside of a first semiconductor die 310 (e.g., a side opposite a front side of the die having a plurality of bond pads 312) can be attached to the upper surface 333a of the redistribution structure 330 via a die-attach material 309. A second semiconductor die 320 having a plurality of bond pads 322 can be stacked on the first semiconductor die 310, and a molded material 350 can be formed on the upper surface 333a of the redistribution structure 330 and around the first and second semiconductor dies 310 and 320. The second semiconductor die 320 is positioned such that a front side of the second semiconductor die 320 including bond pods 322 faces the front side of the first semiconductor die 310. A plurality of conductive features 315 couple at least some of the bond pads 322 of the second semiconductor die 320 to corresponding ones of the bond pads 312 of the first semiconductor die 310. In some embodiments, the conductive features 315 are copper pillars. In certain embodiments, the conductive features 315 can comprise one or more conductive materials such as, for example, copper, gold, aluminum, etc., and can have different shapes and/or configurations.

As further shown in FIGS. 3A and 3B, the bond pads 312 of the first semiconductor die 310 can be electrically coupled to corresponding ones of contacts 334 of the redistribution structure 330 via wire bonds 304. In some embodiments, the conductive features 315 can be formed—and thus the second semiconductor die 320 attached—after forming the wire bonds 304. In certain embodiments, the conductive features 315 can be formed by a suitable process such as, for example, thermo-compression bonding (e.g., copper-copper (Cu—Cu) bonding). In general, thermo-compression bonding techniques can utilize a combination of heat and compression (e.g., z-axis and/or vertical force control) to form a conductive solder joint between the bond pads 312 and 322 of the first and second semiconductor dies 310 and 320, respectively. The conductive features 315 can further be formed to have a height sufficient that the front side of the second semiconductor die 320 does not contact, and possibly damage, the wire bonds 304. In such embodiments, the device 300 includes a gap 317 formed interstitially between the first and second semiconductor dies 310 and 320. In certain embodiments, the gap 317 is filled with the molded material 350 such that the molded material 350 strengthens the coupling between the first and second semiconductor dies 310 and 320. Moreover, the molded material 350 can provide structural strength to the die stack 308 to prevent, for example, bending or warping of the second semiconductor die 320.

FIG. 3B shows one exemplary embodiment of an arrangement of wire bonds 304 electrically coupling the bond pads 312 (FIG. 3A) of the first semiconductor die 310 to the contacts 334 of the redistribution structure 330. The first semiconductor die 310 and bond pads 312 are not pictured in FIG. 3B because they are entirely below the second semiconductor die 320, and the molded material 350 is not pictured for clarity in FIG. 3B. As illustrated, each contact 334 is wire bonded to only a single bond pad 312. However, the wire bonds 304 can be arranged in any other manner to provide a different configuration of electrical couplings between the bond pads 312 and the contacts 334. For example, in other embodiments, some or all of the contacts 334 can be wire bonded to more than one of the bond pads 312. In yet other embodiments, some or all of the contacts 334 can be wire bonded to the bond pads 322 of the second semiconductor die 320, and/or to the conductive features 315.

FIG. 4A is a cross-sectional view, and FIG. 4B is a top plan view, illustrating a semiconductor device 400 (“device 400”) in accordance with another embodiment of the present technology. In this example, one or more semiconductor dies are arranged in a “back-to-back” configuration. The device 400 can include features generally similar to those of the semiconductor devices 100 and 200 described in detail above. For example, in the embodiment illustrated in FIG. 4A, the device 400 includes a redistribution structure 430 having an upper surface 433a, a die stack 408 coupled to the upper surface 433a, and a molded material 450 over the upper surface 433a and encapsulating the die stack 408. More specifically, the redistribution structure 430 can include a plurality of first contacts 434a and a plurality of second contacts 434b (collectively “contacts 434”) exposed at the upper surface 433a of the redistribution structure 430. The second contacts 434b are positioned under the die stack 408 (e.g., positioned within a die-attach area that is directly under a first semiconductor die 410), while the first contacts 434a are spaced laterally away from the die stack 408 (e.g., positioned outboard of the die-attach area).

The first semiconductor die 410 has a plurality of bond pads 412 and is attached to the redistribution structure 430 such that a front side of the semiconductor die 410 (e.g., a side including bond pads 412) faces the upper surface 433a of the redistribution structure 430. The first semiconductor die 410 can be attached to the redistribution structure 430 in this manner using known flip-chip mounting technologies. As shown, a plurality of conductive features 416 can couple the bond pads 412 of the first semiconductor die 410 to corresponding ones of the second contacts 434b of the redistribution structure 430. In some embodiments, the conductive features 416 are copper pillars. In other embodiments, the conductive features 416 can comprise one or more conductive materials such as, for example, copper, gold, aluminum, etc., and can have different shapes and/or configurations. The conductive features 416 can be formed by a suitable process such as, for example, thermo-compression bonding (e.g., copper-copper (Cu—Cu) bonding). In some embodiments, the conductive features 416 have a height such that the device 400 includes a gap 418 formed interstitially between the first semiconductor die 410 and the upper surface 433a of the redistribution structure 430. In some such embodiments, the gap 418 is filled with the molded material 450 to strengthen the coupling between the first semiconductor die 410 and the redistribution structure 430. Moreover, the molded material 450 can strengthen the die stack 408 to prevent, for example, bending or warping of the first semiconductor die 410.

A second semiconductor die 420 having a plurality of bond pads 422 can be stacked back-to-back on the first semiconductor die 410 (e.g., a back side of the first semiconductor die 410 faces a back side of the second semiconductor die 420). The second semiconductor die 420 can be attached to the first semiconductor die 410 via a die-attach material 409. As further shown in FIGS. 4A and 4B, the bond pads 422 of the second semiconductor die 420 can be electrically coupled to corresponding ones of first contacts 434a of the redistribution structure 430 via wire bonds 404. As shown in FIG. 4B, some of the first contacts 434a of the redistribution structure 430 may be electrically coupled, via individual wire bonds 404 to more than one of the bond pads 422 of the second semiconductor die 420. Likewise, some of the first contacts 434a of the redistribution structure 430 may be coupled to only a single bond pad 422 of the second semiconductor die 420. However, the wire bonds 404 can be arranged in any other manner to provide a different configuration of electrical couplings between the bond pads 422 and the first contacts 434a. For example, in some embodiments, each first contact 434a is wire bonded to only a single corresponding bond pad 422.

In other embodiments of the present technology, a semiconductor device including a die stack with more than two dies can be provided using any of the front-to-back, front-to-front, and/or back-to-back arrangements described herein with reference to FIGS. 1A-4B, or any combinations thereof. For example, a semiconductor device according to the present technology can include multiple front-to-front pairs of semiconductor dies stacked 4-high, 6-high, 8-high, etc., multiple front-to-back pairs of semiconductor dies stacked 4-high, 6-high, 8-high, etc., or any other combination.

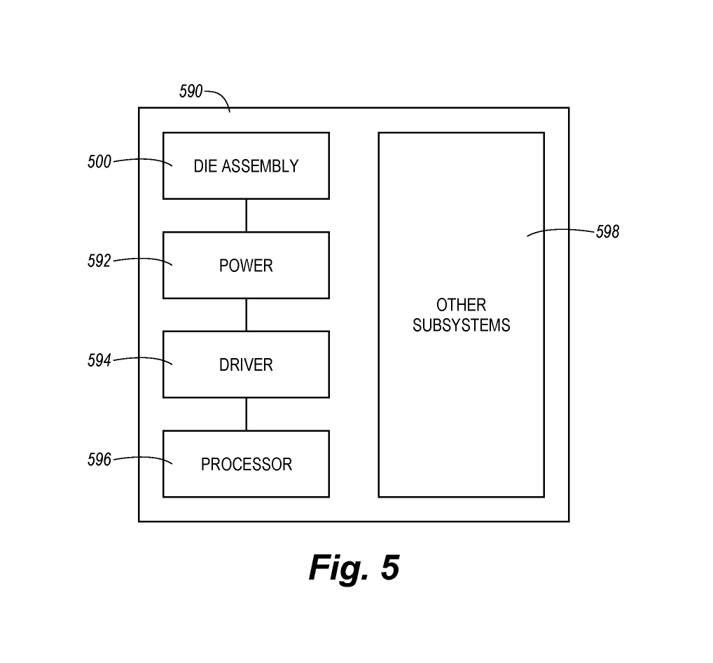

Any one of the semiconductor devices described above with reference to FIGS. 1A-4B can be incorporated into any of a myriad of larger and/or more complex systems, a representative example of which is system 590 shown schematically in FIG. 5. The system 590 can include a semiconductor die assembly 500, a power source 592, a driver 594, a processor 596, and/or other subsystems or components 598. The semiconductor die assembly 500 can include semiconductor devices with features generally similar to those of the semiconductor devices described above. The resulting system 590 can perform any of a wide variety of functions, such as memory storage, data processing, and/or other suitable functions. Accordingly, representative systems 590 can include, without limitation, hand-held devices (e.g., mobile phones, tablets, digital readers, and digital audio players), computers, and appliances. Components of the system 590 may be housed in a single unit or distributed over multiple, interconnected units (e.g., through a communications network). The components of the system 590 can also include remote devices and any of a wide variety of computer readable media.

From the foregoing, it will be appreciated that specific embodiments of the technology have been described herein for purposes of illustration, but that various modifications may be made without deviating from the disclosure. Accordingly, the invention is not limited except as by the appended claims. Furthermore, certain aspects of the new technology described in the context of particular embodiments may also be combined or eliminated in other embodiments. Moreover, although advantages associated with certain embodiments of the new technology have been described in the context of those embodiments, other embodiments may also exhibit such advantages and not all embodiments need necessarily exhibit such advantages to fall within the scope of the technology. Accordingly, the disclosure and associated technology can encompass other embodiments not expressly shown or described herein.

I/We claim:

1. A semiconductor device, comprising:
a redistribution structure having a dielectric material, a first surface having first conductive contacts, a second surface having second conductive contacts, and conductive lines electrically coupling individual ones of the first conductive contacts to corresponding ones of the second conductive contacts through the dielectric material, and wherein the redistribution structure does not include a pre-formed substrate;
a semiconductor die coupled to the first surface of the redistribution structure and including bond pads;
wire bonds electrically coupling the bond pads to corresponding ones of the first conductive contacts; and
a molded material covering at least a portion of the redistribution structure and the semiconductor die.

2. The semiconductor device of claim 1 wherein the semiconductor die is a first semiconductor die, wherein the bond pads are first bond pads, and further comprising a second semiconductor die stacked over the first semiconductor die and including second bond pads.

3. The semiconductor device of claim 2 wherein the wire bonds are first wire bonds, and further comprising second wire bonds electrically coupling the second bond pads to corresponding ones of the first conductive contacts of the redistribution structure.

4. The semiconductor device of claim 2, further comprising a first die-attach material between the first semiconductor die and the first surface of the redistribution structure, and a second die-attach material between the second semiconductor die and the first semiconductor die.

5. The semiconductor device of claim 2 wherein the first bond pads face the second bond pads, and wherein the second bond pads are electrically coupled to the redistribution structure.

6. The semiconductor device of claim 1 wherein the semiconductor die is a first semiconductor die, and further comprising a second semiconductor die, wherein:
the first semiconductor die is stacked over the second semiconductor die, and
the second semiconductor die is coupled to the redistribution structure and electrically coupled to at least one of the first conductive contacts.

7. The semiconductor device of claim 6 wherein the second semiconductor die includes bond pads electrically coupled to corresponding ones of the first conductive contacts via a solder connection.

8. The semiconductor device of claim 6 wherein the redistribution structure further includes a die-attach area under the second semiconductor die, and wherein the second semiconductor die is electrically coupled only to first contacts that are within the die-attach area.

9. The semiconductor device of claim 6 wherein the redistribution structure further includes a die-attach area under the second semiconductor die, and wherein the bond pads are electrically coupled by the plurality of wire bonds to first contacts that are outside of the die-attach area.

10. The semiconductor device of claim 1 wherein the semiconductor die is a memory die.

11. The semiconductor device of claim 1, wherein:
the molded material is over the first surface of the redistribution structure, and encapsulates the semiconductor die and the plurality of wire bonds; and
the device further comprises a die-attach material between the semiconductor die and the first surface of the redistribution structure.

12. The semiconductor device of claim 1 wherein at least one of the second contacts is spaced laterally farther from the semiconductor die than the corresponding first contact to which the second contact is electrically coupled.

13. The semiconductor device of claim 1 wherein a thickness of the redistribution structure between the first and second surfaces is less than about 50 μm.

14. A method of manufacturing a semiconductor device, the method comprising:
forming a redistribution structure on a carrier, the redistribution structure including an insulating material, first conductive contacts at a first surface of the redistribution structure, and second conductive contacts at a second surface of the redistribution structure, wherein the second conductive contacts are electrically coupled to corresponding ones of the first conductive contacts via conductive lines that extend at least partly through the insulating material;
disposing a semiconductor die over the first surface of the redistribution structure, wherein the semiconductor die includes bond pads;
coupling the bond pads to corresponding ones of the first conductive contacts with wire bonds;
forming a molded material over at least a portion of the first surface of the redistribution structure, the semiconductor die, and the wire bonds; and
removing the carrier to expose the second surface of the redistribution structure and the second conductive contacts.

15. The method of claim 14 wherein the semiconductor die is a first semiconductor die, wherein the bond pads are first bond pads, and the method further comprises:
stacking a second semiconductor die on the first semiconductor die, wherein the second semiconductor die includes second bond pads; and
coupling the second bond pads to corresponding ones of the first conductive contacts with wire bonds.

16. The method of claim 14 wherein the semiconductor die is a first semiconductor die, and the method comprises:
attaching a second semiconductor die to the first surface of the redistribution structure, wherein the first semiconductor die is stacked on the second semiconductor die, and wherein the second semiconductor die is electrically coupled to at least one of the first conductive contacts.

17. The method of claim 14, further comprising, after removing the carrier, disposing conductive features on the exposed second conductive contacts.

18. The method of claim 14, further comprising:
coupling a plurality of semiconductor dies to the first surface of the redistribution structure, wherein each semiconductor die includes bond pads;
coupling the bond pads of each semiconductor die to corresponding ones of the first conductive contacts with wire bonds; and
after removing the carrier, singulating the resulting structure to define a plurality of individual semiconductor devices.

19. A semiconductor device package, comprising:
a first semiconductor die;
a redistribution structure including a built-up dielectric material formed directly on the first semiconductor die, a first side having first bond pads, a second side having package contacts, and conductive lines electrically coupling individual ones of the first bond pads to corresponding ones of the package contacts through the dielectric material, wherein the first side of the redistribution structure is attached to the first semiconductor die, and wherein the first semiconductor die has second bond pads electrically coupled to corresponding ones of the first bond pads of the redistribution structure;
a second semiconductor die stacked over the first semiconductor die and having third bond pads; and
first wire bonds electrically coupling the third bond pads to corresponding ones of the first bond pads.

20. The semiconductor device package of claim 19 wherein the second bond pads are electrically coupled to the corresponding ones of the first bond pads via second wire bonds.

21. The semiconductor device package of claim 19 wherein the second bond pads face the first side of the redistribution structure and are electrically coupled to the corresponding ones of the first bond pads via conductive features.

22. The semiconductor device package of claim 19, further comprising a molded material over the first side of the redistribution structure and encapsulating the first semiconductor die, the second semiconductor die, and the first wire bonds.

23. The semiconductor device package of claim 19, further comprising a third semiconductor die stacked over the second semiconductor die and having fourth bond pads, wherein the fourth bond pads are electrically coupled to corresponding ones of the first bond pads of the redistribution structure.

24. The semiconductor device package of claim 19 wherein a thickness of the redistribution structure between the first and second sides is less than about 50 μm.
